(19) United States
(12) Patent Application Publication
(10) Pub. No.: US 2010/0171132 A1
(43) Pub. Date: Jul. 8, 2010

(54) LIGHT EMITTING DEVICE AND METHOD FOR FABRICATING THE SAME

(75) Inventors: Do Yeol Ahn, Seoul (KR); Seoung Hwan Park, Daegu (KR)

Correspondence Address: HUSCH BLACKWELL SANDERS LLP, 190 Carondelet Plaza, Suite 600, ST. LOUIS, MO, 63105, US

(73) Assignee: WOOREELST CO., LTD, Gyeonggi-do (KR)

(21) Appl. No.: 12/601,901

(22) PCT Filed: May 22, 2008
(86) PCT No.: PCT/KR08/02868

§ 371 Date: Nov. 25, 2009

(30) Foreign Application Priority Data
May 28, 2007 (KR) 10-2007-0051356

(51) Int. Cl. H01L 33/00

(52) U.S. Cl. 257/94; 257/E33.016

(57) ABSTRACT

A light-emitting device is provided. The light-emitting device comprises a light-emitting layer having a first quaternary clad layer with a first material having a first composition ratio and a second material having a second composition ratio, a second quaternary clad layer with a third material having a third composition ratio and a fourth material having a fourth composition ratio, and an activation layer contacted with first clad layer and the second clad layer between them; a first electrode electrically contacted with the light-emitting layer; and, a second electrode electrically contacted with the light-emitting layer, wherein the first quaternary clad layer and the second quaternary clad layer have a predetermined energy band gap by controlling the first, second, third and fourth composition ratio, for removing the piezoelectric field and spontaneous polarization applied to the activation layer.

### TECHNICAL FIELD

The present invention relates to a light-emitting device. More particularly, the present invention relates to a light-emitting device with improved light-emission efficiency and a method for fabricating the light-emitting device.

### BACKGROUND ART

Light-emitting diodes (LEDs) were first researched in the early 1960s and have been commercially available since the late 1960s. Since the 1960s, LEDs have received a great deal of attention, based on their superior characteristics such as vibration resistance, high reliability and low power consumption. However, initially-developed LEDs had a limited range of applications, such as display lamps in spaceships and aircraft, due to their high price.

LEDs include a light-emitting device which converts applied electric energy into light, to emit light.

All substances consist of atoms, each of which has a nucleus. The electron revolves in a circular orbit around the nucleus. The further the distance between the orbit and the nucleus, the higher the energy the electron revolving in the orbit has.

When an electron revolving in a lower orbit gains energy from an external source, it jumps from the allowed orbit to a higher orbit. An unstable electron revolving in a higher orbit falls into a lower orbit by releasing energy. LEDs convert the released energy into light.

LEDs differ in levels to which electrons jump or fall according to materials thereof and thus generate different levels of energy. Specifically, when the light is generated in a low energy level, it has a long wavelength and renders red, and on the other hand, when the light is generated in a high energy level, it has a short wavelength and renders blue.

Based on such a principle, three colors (i.e. red, green and blue) of LEDs are combined to realize full-color.

Of these, red LEDs were the first to become commercially available. In particular, GaAsP-based red LEDs were first introduced by General Electric Corp., in 1962.

Initially-developed LEDs were fabricated on a small scale and thus exhibited low performance. However, since LEDs were mass-produced by Monsanto and Hewlett-Packard in the late 1960s, they have been intensely researched and practically used in the U.S.

When heterojunction red LEDs in which GaAlAs is developed on a GaAs substrate were developed, a great deal of intense research was devoted to red LEDs in Japan during the 1980s and high-brightness red LEDs have been commercially available since then. In particular, green LEDs employing AlGaAs as a material came into the spotlight, because they exhibited higher energy conversion efficiency than incandescent lamps (i.e., 1%).

A great deal of research continues to be devoted to the development of novel semiconductor materials. Recent technical progress in the development of quaternary compounds (e.g. indium gallium aluminum phosphide (nitride) (InGaAlP(InGaAlN)) semiconductor thin films) ensures LEDs with high brightness and high luminescence, as compared to incandescent lamps.

The term “compound semiconductor” as used herein refers to a semiconductor composed of a compound of two or more elements. Examples of compound semiconductors include: Group III-V compound semiconductors such as gallium arsenide (GaAs), indium phosphide (InP), gallium phosphide (GaP) compound semiconductors; Group II-VI compound semiconductors such as cadmium sulfide (CdS) and zinc telluride (ZnTe) compound semiconductors; and Group IV-VI compound semiconductors such as lead sulfide (PbS) compound semiconductors.

Compound semiconductors are different from single-element semiconductors, e.g., germanium (Ge) or silicon (Si) semiconductors, in terms of carrier mobility and band structure. This carrier mobility and band structure difference leads to large differences in electrical and optical properties between the two types of semiconductors. Compound semiconductors with desired properties, selected from various compound semiconductors, are used to fabricate LEDs which cannot be realized with the single-element (e.g. silicon (Si) and germanium (Ge)) semiconductors.

FIG. 1 is a sectional view illustrating a general Group III-V nitride semiconductor light-emitting diode.

Referring to FIG. 1, a general Group III-V nitride semiconductor light-emitting diode 1 comprises a buffer layer 50 doped with conductive impurities, a light-emitting layer 10 arranged on the buffer layer 50, a first electrode 60 arranged under the buffer layer 50 and a second electrode 70 arranged on the light-emitting layer 10.

The light-emitting layer 10 comprises a first clad layer 20 generating carriers for light-emission from an electric field applied through the buffer layer 50, a second clad layer 40 generating carriers for light-emission from an electric field applied from the second electrode 70, and an activation layer 30 interposed between the first clad layer 20 and the second clad layer 40 and emitting light.

The first clad layer 20 and the second clad layer 40 constituting the light-emitting layer 10 are semiconductor layers made of a combination of Group III-V elements e.g. InGaAlP, and the activation layer 30 is a semiconductor layer made of a combination of Group III-V elements e.g. InGaP.

The structure of the light-emitting diode 1 enables conversion of electric energy derived from an electric field applied to both the electrodes 60 and 70 into light energy, to emit light.

Group III-V compound semiconductors constituting LEDs that emit celadon green and bluish green light have structural drawbacks in that stress inevitably applied to the light-emitting layer 10, causes formation of piezoelectric fields in the first and second clad layers 20 and 40, as shown in FIG. 2, thus resulting in physical deformation of the light-emitting layer 10.

Disadvantageously, due to spontaneous polarization, group III-V compound semiconductors have considerably lower luminescence than other compound semiconductors.

A theoretical model for such a phenomenon was grounded on Park et al., Appl. Phys. Lett. 75. 1354 (1999).

In particular, several methods for removing spontaneous polarization have been reported to date. For example, non- or semi-polar substrates, which vary a specific direction in which crystals are developed on a substrate, may be used. Another method is to form clad layers with quaternary compound films in which an aluminum (Al) composition in the quaternary compound is increased, to improve carrier confinement effects and increase luminescent efficiency.

The theoretical ground for the use of the non- or semi-polar substrates was disclosed in Park & Chuang, Phys. Rev. B59, 4725 (1999), Waltereit et al., Nature 406, 865 (2000).

However, non- or semi-polar substrates have difficulty realizing high quality due to incomplete techniques for development of crystals in the crystal development direction.

In order to obtain non- or semi-polar substrates with high-quality, several epitaxy processes must be carried out. This requirement entails a complicated fabrication process, deteriorated fabrication efficiency and increased fabrication cost.

The formation of the first and second clad layers 20 and 40 with an aluminum (Al)-containing quaternary compound semiconductor in which a composition of the aluminum (Al) is increased, is disclosed in Zhang et al., Appl. Phys. Lett. 77, 2668 (2000)], Lai et al., IEEE Photonics Technol. Lett. 13, 559 (2001)].

However, these methods cannot fundamentally eliminate the phenomena of piezoelectric fields and spontaneous polarization. Thus, the problem of deteriorated luminescence properties of LEDs remains unsolved.

### DISCLOSURE

### Technical Problem

An object of the present invention devised to solve the problem lies on a compound semiconductor light-emitting device with improved light-emission efficiency by which piezoelectric fields and spontaneous polarization are removed from a light-emitting layer, and a method for fabricating the light-emitting device.

### Technical Solution

The object of the present invention can be achieved by providing a quaternary nitride semiconductor light-emitting diode comprising: a buffer layer doped with conductive impurities; a light-emitting layer arranged on the buffer layer; a first electrode arranged under the buffer layer; and a second electrode arranged on the light-emitting layer, wherein the light-emitting layer includes a first clad layer, an activation layer arranged on the first clad layer, and a second clad layer arranged on the activation layer, wherein the first clad layer includes a first material having a first composition and a second material having a second composition, and the second clad layer includes a third material having a third composition different from the first composition, and a fourth material having a fourth composition different from the second composition.

The first and second clad layers may be composed of AlₓIn_{y}Ga_{1-x-y}N.

The first and second clad layers may be composed of CdₓMg_{y}Zn_{1-x-y}O.

The first and second clad layers may have an energy band gap of 4.0 eV.

In another aspect of the present invention, provided herein is a method for fabricating a compound semiconductor light-emitting diode comprising: forming a sacrificial layer on a substrate; forming a conductive impurity-doped buffer layer on the sacrificial layer; forming a single-crystal first clad layer on the buffer layer wherein the first clad layer includes a first material having a first composition and a second material having a second composition; forming an activation layer on the first clad layer; forming a second clad layer on the activation layer such that the second clad layer includes a third material having a third composition different from the first composition, and a fourth material having a fourth composition different from the second composition; removing the sacrificial layer; and forming a first electrode under the buffer layer and a second electrode on the second clad layer.

In a further aspect of the present invention, provided herein is a method for fabricating a compound semiconductor light-emitting diode comprising: forming a sacrificial layer on a substrate; forming a conductive impurity-doped buffer layer on the sacrificial layer; forming a single-crystal first clad layer on the buffer layer such that the first clad layer is composed of a first material having a first composition and a second material having a second composition; removing the sacrificial layer; forming an activation layer on the first clad layer; forming a second clad layer on the activation layer such that the second clad layer includes a third material having a third composition different from the first composition, and a fourth material having a fourth composition different from the second composition; and forming a first electrode under the buffer layer and a second electrode on the second clad layer.

The compositions of the first to fourth materials may be controlled such that the first and second clad layers have an energy band gap of 4.0 eV.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 is a sectional view illustrating a general Group III-V nitride semiconductor light-emitting diode;

FIG. 2 is a sectional view showing deformation of a light-emitting layer resulting from piezoelectric fields;

FIG. 3 is a sectional view illustrating the structure of a quaternary nitride compound semiconductor light-emitting diode according to an embodiment of the present invention;

FIG. 4 is a sectional view illustrating a state in which stress is applied to an activation layer and clad layers in a semiconductor including n layers;

FIG. 5 are graphs showing behavior of stress applied to the activation layer under various aluminum (Al) and indium (In) compositions of a quaternary nitride compound semiconductor clad layer;

FIG. 6 is a graph showing behavior of piezoelectric fields and spontaneous polarization generated on the activation layer and clad layers of the quaternary nitride compound semiconductor according to an embodiment of the present invention;

FIG. 7 is a graph showing variation in internal fields applied to the activation layer of the quaternary nitride compound semiconductor according to an embodiment of the present invention;

FIG. 8 is a graph comparing optical gain between the quaternary nitride compound semiconductor light-emitting diode according to an embodiment of the present invention, and a non-polar substrate-employing light-emitting diode;

FIG. 9 is a graph comparing optical property between the quaternary nitride compound semiconductor light-emitting diode according to an embodiment of the present invention, and a non-polar substrate-employing light-emitting diode; and

FIGS. 10 and 16 are sectional views illustrating a method for fabricating the quaternary nitride compound semiconductor according to an embodiment of the present.

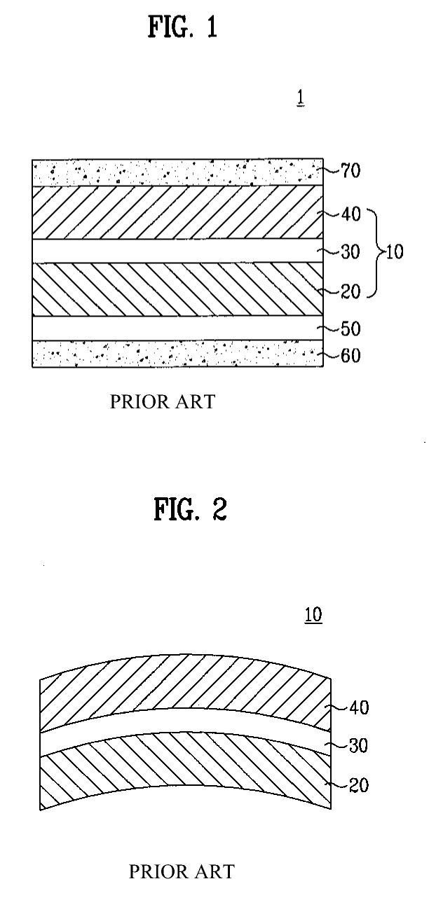

### BEST MODE

Reference will now be made in detail to the preferred embodiments of the present invention, examples of which are illustrated in the accompanying drawings.

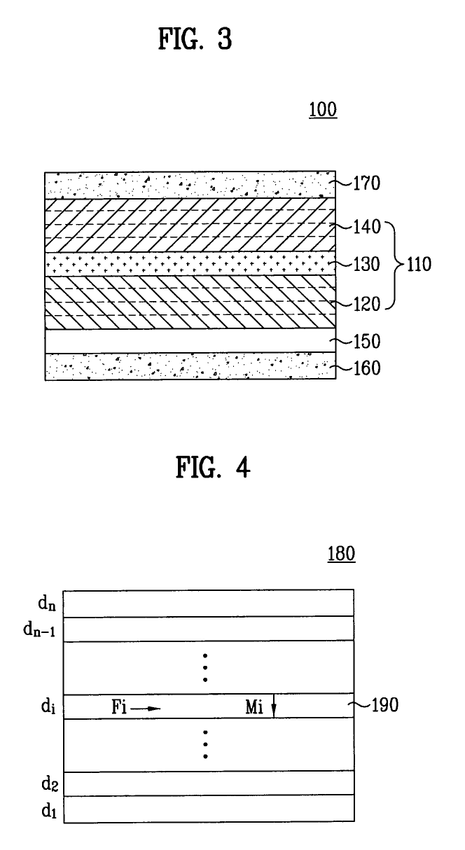

FIG. 3 is a sectional view illustrating the structure of a quaternary nitride compound semiconductor light-emitting diode according to an embodiment of the present invention.

Referring to FIG. 3, a quaternary nitride semiconductor light-emitting diode 100 according to an embodiment of the present invention comprises a buffer layer 150 doped with conductive impurities, a light-emitting layer 110 arranged on the buffer layer 150, a first electrode 160 arranged under the buffer layer 150 and a second electrode 170 arranged on the light-emitting layer 100.

The light-emitting layer 110 includes a first clad layer 120 generating carriers for light-emission from an electric field applied through the buffer layer 150, a second clad layer 140 generating carriers for light-emission from an electric field applied from the second electrode 170, and an activation layer 130 interposed between the first clad layer 130 and the second clad layer 150 and emitting light.

The first clad layer 120 and the second clad layer 140 constituting the light-emitting layer 110 are single-crystal semiconductor layers having a quantum well layer made of a compound of Group III-V elements (e.g. AlₓIn_{y}Ga_{1-x-y}N), and the activation layer 130 is a single-crystal semiconductor layer made of a compound of Group III-V elements e.g. GaN.

Based on the structure of the light-emitting diode 100, the light-emitting layer 110 converts electric energy, which is derived from an electric field applied to the first electrode 160 and the second electrode 170 arranged in lower and upper parts of the light-emitting diode 100, respectively, to light energy, to emit light.

In the quaternary compound film of AlₓIn_{y}Ga_{1-x-y}N, constituting the first clad layer 120 and the second clad layer 140 in the light-emitting layer 110, an aluminum (Al) composition X and an indium (In) composition Y are combined in an appropriate ratio, such that the first and second clad layers 120 and 140 have an energy band gap (i.e. about 4.0 eV), comparable to general ternary compound clad layers.

More specifically, among elements constituting the quaternary compound film of the first and second clad layers 120 and 140, the aluminum (Al) composition X and the indium (In) composition Y are adjusted in the range of 0<X<0.4 and 0<Y<0.4, respectively, such that the first and second clad layers 120 and 140 have an energy band gap of about 4.0 eV.

By employing aluminum (Al) and indium (In) compositions which eliminates internal fields of the activation layer 130 resulting from piezoelectric fields and spontaneous polarization, under the condition that the first and second clad layers 120 and 140 have an energy band gap of about 4.0 eV, it is possible to improve light generation efficiency of the activation layer 130.

The aluminum (Al) and indium (In) compositions of the first clad layer 120 may be symmetrical to those of the second clad layer 140 within the respective predetermined ranges.

Specifically, in a case where the aluminum (Al) composition X of the first clad layer 120 and the second clad layer 140 is in the range of 0<X<0.4, when aluminum (Al) of the first clad layer 120 has a first composition, aluminum (Al) of the second clad layer 140 has a second composition B different from the first composition A. For example, when the first composition A is 0.1, the second composition is 0.3.

By symmetrically controlling aluminum (Al) compositions X of first and second clad layers 120 and 140 within the desired ranges, it is possible to offset the activation layer 130 and prevent spontaneous polarization.

Similarly, by symmetrically controlling indium (In) compositions Y of first and second clad layers 120 and 140 within the desired ranges, it is possible to offset stresses applied to the activation layer 130 and prevent spontaneous polarization.

FIG. 4 is a sectional view illustrating a state in which stress is applied to the activation layer and clad layers in a semiconductor including n layers.

As shown in FIG. 4, in a semiconductor layer 180 having n layers, the stress Fi applied to an ith layer 190 is calculated according to the following Equation 1. The theoretical basis thereof is disclosed in K. Nakajima, J. Appl. Phys. 72. 5213 (1992).

$${F}_{i} = \frac{{E}_{i} {d}_{i}}{{a}_{i} Q \frac{{E}_{j} {d}_{j}}{{a}_{j}}} s [ \begin{matrix}\frac{1}{R} {Q}_{j} ( \frac{{E}_{j} {d}_{j}}{{a}_{j}} ) \{ \begin{matrix}{Q}_{k < i} {a}_{k} {d}_{k} - {Q}_{k < j} {a}_{k} {d}_{k} + \\ \frac{{a}_{i} {d}_{i} - {a}_{j} {d}_{j}}{2}\end{matrix} \} + \\ {Q}_{j} ( \frac{{E}_{j} {d}_{j}}{{a}_{j}} ) ( {l}_{j} - {l}_{i} )\end{matrix} ] \qquad Equation 1$$

wherein dᵢ is a thickness of the i^{th} layer of n layers, aᵢ is a lattice constant of the i^{th} layer, Eᵢ is the Young's modulus, and Li is an effective lattice constant of the i^{th} layer, reflecting thermal expansion, as is given by the following Equations 2 to 5.

The term “Young's modulus” as used herein refers to an elastic modulus introduced by T. Young in 1807.

When both ends of a bar having a uniform thickness are drawn, a deformation force T exerted by the bar is proportional to tensile strain A of an amount by which the length of the bar changes (compression or stretching) per an original length, within an elastic limit. The ratio E=T/A refers to the Young's modulus, also known as “elastic modulus”. The Young's modulus of a physical body is a fixed value, independent of thickness and length.

$$\begin{matrix}i = {a}_{i} ( 1 + {α}_{i} T ) & Equation 2 \\ {l}_{i + 1} [ 1 + {e}_{i + 1} ( {F}_{i + 1} ) - {e}_{i + 1} ( {M}_{i + 1} ) ] = {l}_{i} [ 1 + {e}_{i} ( {F}_{i} ) + {e}_{i} ( {M}_{i} ) ] & Equation 3 \\ {e}_{i} ( {F}_{i} ) = \frac{{F}_{i}}{{E}_{i} {d}_{i}} & Equation 4 \\ {e}_{i} ( {M}_{i} ) = \frac{{d}_{i}}{2 R} & Equation 5\end{matrix}$$

In the Equations, eᵢ is an effective strain applied to the i^{th} layer among n layers, and R is a curvature of a substrate. The curvature of the sapphire substrate is in the range of 6 m to 12 m.

It can be confirmed from the Equations above that in the case of N=3, the quaternary compound has a desired composition, enabling efficient elimination of the strain of the activation layer 130.

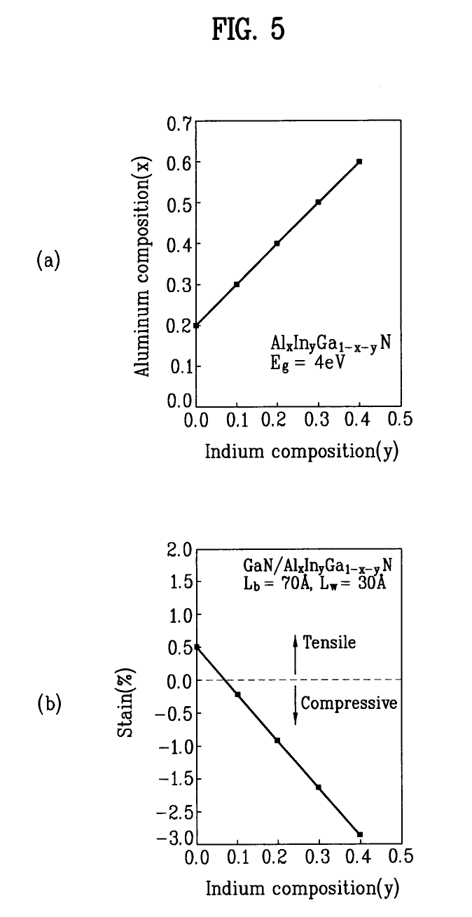

(a) Of FIG. 5 is a graph showing a relation between an aluminum (Al) composition X and an indium (In) composition Y of the quaternary compound semiconductor wherein the energy band gap (Eg) of the first clad layer 120 and the second clad layer 140 maintains 4 eV. As shown in (a) of FIG. 5, when the aluminum (Al) composition X and the indium (In) composition are controlled such that the energy band gap (Eg) of the first clad layer 120 and the second clad layer 140 maintains 4.0 eV, the two compositions are linearly related to each other.

(b) of FIG. 5 is a graph showing a behavior of strain applied to an activation layer 130 according to variation in the indium (In) composition, under the condition that the energy band gap (Eg) of the first clad layer 120 and the second clad layer 140 is maintained at 4.0 eV.

Referring to (b) of FIG. 5, under this energy band gap condition, when no indium (In) is added, a tensile stress is applied to the first clad layer 120 and the second clad layer 140.

On the other hand, when the indium (In) composition is increased, a compressive stress is applied to the first clad layer 120 and the second clad layer 140.

The term “stress” as used herein, also known as “deformation force”, refers to an internal force acting within a body to maintain its shape, as a reaction to external applied forces.

Based on the direction in which a force acts to the major axis of a body, the stress is divided into shearing stress, tensile stress (also known as “tension”) and compressive stress. Even at the same site in a body, the type and intensity of stresses are varied depending upon the direction in which a force acts to the major axis of the body.

When both ends of a bar having a uniform cross-section are drawn with a force P, the bar is stretched by the force P. As the force is increased, the bar is finally broken (cut). In response to the force P, a number of actions/reactions (herein, referred to as internal forces) occur between a large number of fine particles within the body.

Although these internal forces are invisible, it may be assumed that the bar has an imaginary cross-section m-n cut perpendicular to its major axis. In this case, in a lower part of the cross-section m-n, an external force p acts from the bottom of the bar to the outside, and in an upper part of the cross-section m-n, internal forces act between high-level particles and low-level particles. The internal forces are uniformly distributed on the cross-section. A sum of the internal forces m-n corresponds to the external force p acting in the upper part.

Accordingly, a pair of internal forces with the same intensity and opposite direction act to a cross-section inside a body. Such an internal force is referred to as a “stress (deformation force)”.

The tensile stress and compressive stress depend upon the indium (In) composition. Specifically, a turning point between the tensile stress and compressive stress occurs at 6% indium (In). More specifically, when the indium (In) composition is less than 6%, tensile stress is applied, and on the other hand, the indium (In) composition is more than 6%, a compressive stress is applied. In a case where general gallium substrates are developed, when a tensile stress is applied, spontaneous polarization and piezoelectric fields are in parallel. On the other hand, when a compressive stress is applied, spontaneous polarization and piezoelectric fields are formed in opposite directions.

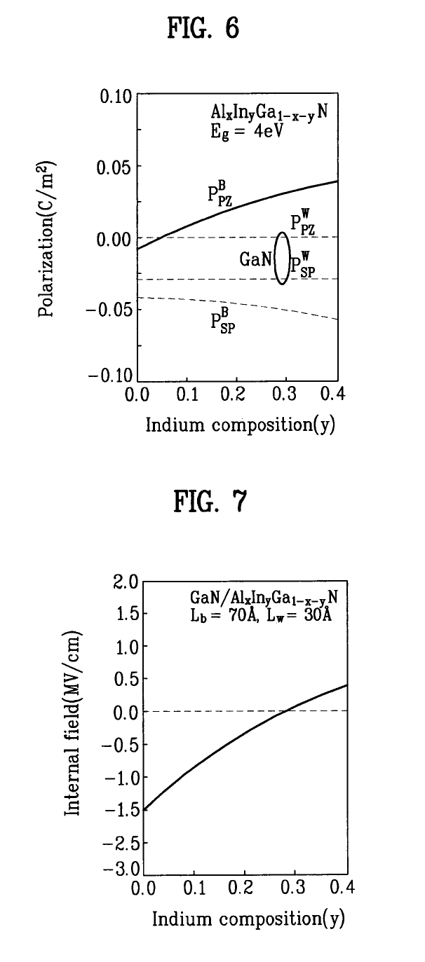

FIG. 6 is a graph showing piezoelectric fields and spontaneous polarization generated on the activation layer and clad layer under various indium (In) compositions, in a quaternary nitride compound semiconductor according to an embodiment of the present invention.

FIG. 6 shows theoretical values of piezoelectric fields and spontaneous polarization applied to the quaternary nitride (GaN/AlInGaN) semiconductor quantum well structure.

The theoretical values shown in FIG. 6 are calculated by setting the thicknesses of the activation layer and the clad layer to 3 nm and 7 nm, respectively. The theoretical models are grounded on Ahn et al., IEEE J Quantum Electron 41, 1253 (2005).

As shown in FIG. 6, by controlling the indium (In) composition of the quaternary nitride (GaN/AlInGaN) semiconductor, it is possible to control spontaneous polarization generated on the activation layer and clad layer.

In addition, the sum of piezoelectric fields and spontaneous polarization applied to the activation layer is calculated by the following Equation 6:

$${F}_{Z}^{W} \frac{[ ( {P}_{SP}^{b} + {P}_{PZ}^{b} ) - ( {P}_{SP}^{w} + {P}_{PZ}^{w} ) ]}{{ɛ}^{w} + \frac{{ɛ}^{b} {L}_{w}}{{L}_{b}}} \qquad Equation 6$$

wherein P is a type of polarization and L is a thickness of the activation layer or the clad layer.

FIG. 7 shows variation in internal field applied to the activation layer calculated according to Equation 6.

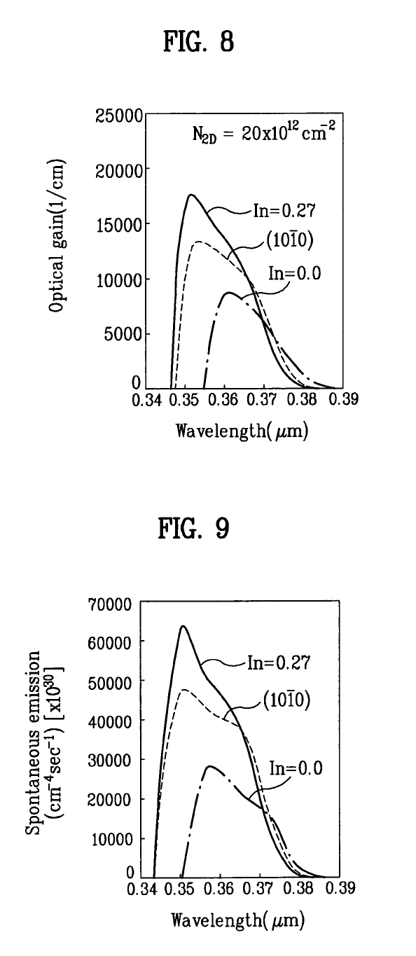

FIG. 8 is a graph comparing optical gain of a quaternary nitride semiconductor light-emitting diode according to an embodiment of the present invention, and a light-emitting diode employing a non-polar substrate. FIG. 9 is a graph comparing optical properties of a quaternary nitride semiconductor light-emitting diode according to an embodiment of the present invention, and a light-emitting diode employing a non-polar substrate.

As can be seen from FIGS. 8 and 9, comparing the nitride semiconductor light-emitting diode according to the embodiment of the present invention with the non-polar substrate-employing light-emitting diode, the quaternary nitride semiconductor light-emitting diode exhibits superior optical properties.

As compared to the case where a non- or semi-polar substrate suffering from incomplete crystal development is used, according to an embodiment of the present invention, quaternary nitride with a desired composition is developed along the crystal development direction [0001], to fabricate a light-emitting diode. As a result, it is possible to realize high fabrication efficiency and high optical efficiency.

As such, the results related to optical gain and optical efficiency are grounded on Ahn, IEEE J. Quantum Electron. 34, 344 (1998) & Ahn et. al., IEEE J. Quantum Electron. 41, 1253 (2005).

As illustrated in the embodiment, the first clad layer 120, the second clad layer 140 and activation layer 130 are Group III-V compound semiconductors employing elements such as aluminum (Al), gallium (Ga), indium (In), phosphorus (P), arsenic (As), nitrogen (N). Alternatively, these layers may employ semiconductors composed of Group II-VI compounds such as ZnO or CdMgZnO.

When the activation layer 130 is a Group III-V nitride compound (AlInGaN) semiconductor, indium (In) and nitrogen (N) compositions are adjusted to InₓGa₁₋ₓN, where 0<X<1. In addition, in the case of Group II-VI compound (e.g. ZnO or CdMgZnO) semiconductors, the activation layer is composed of ZnO and the clad layer is composed of CdₓMg_{y}Zn_{1-x-y}O, in which cadmium (Cd) composition X and magnesium (Mg) composition Y are in the range of 0<X<0.4 and 0<Y<0.33, respectively.

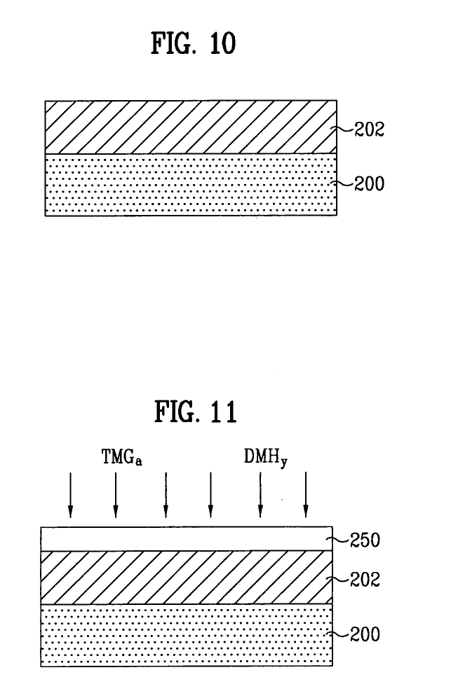

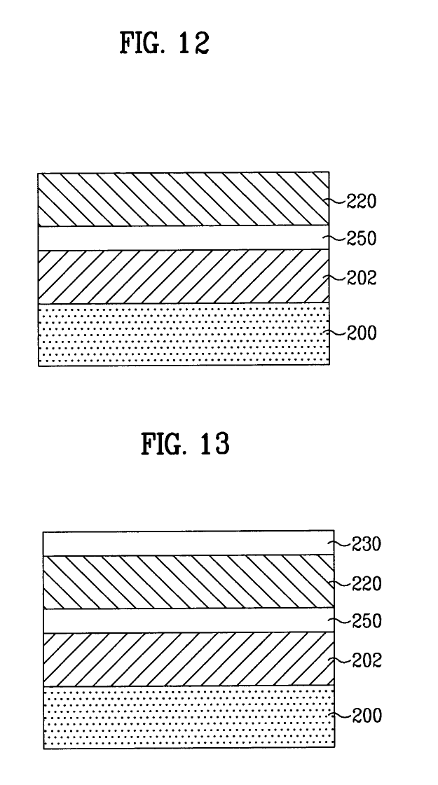

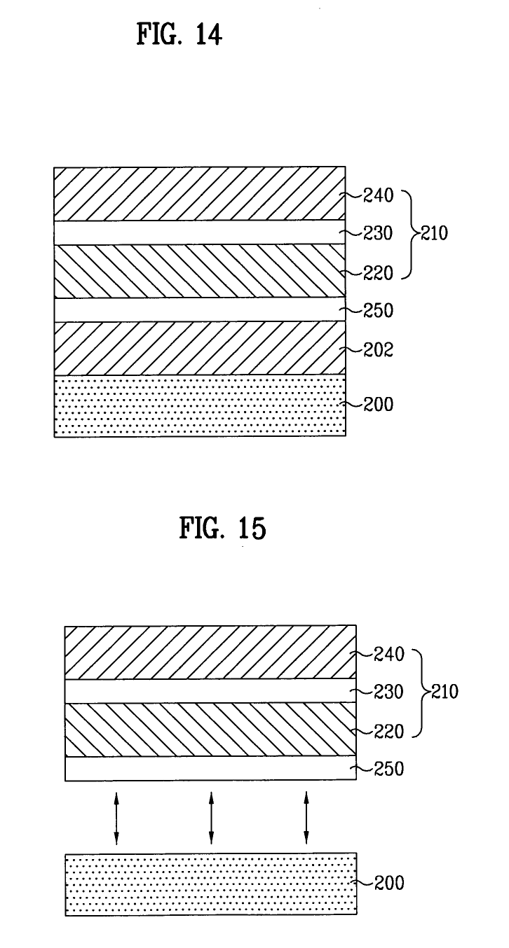

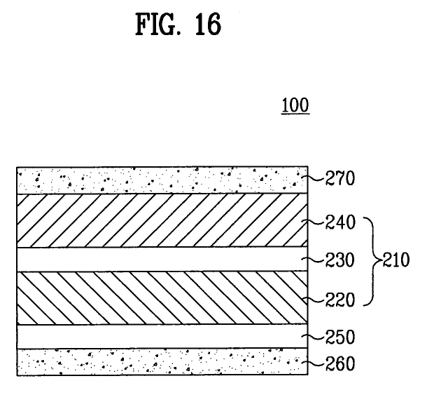

FIGS. 10 and 16 are sectional views illustrating a method for fabricating the quaternary nitride semiconductor light-emitting diode according to an embodiment of the present invention.

Referring to FIGS. 10 and 16, the method for fabricating the light-emitting diode according to an embodiment of the present invention will be illustrated below.

Compound semiconductors, sapphire, SiC, Si, ZrB, CrB, and the like may be used as a substrate 200, on which a nitride compound semiconductor is developed. When a compound semiconductor is directly developed on a substrate, satisfactory crystals cannot be developed thereon due to lattice mismatch. In this case, a buffer layer (e.g. GaN, AlN or SiC) is developed on the substrate and a compound semiconductor is then developed on the resulting structure, thereby developing high-quality crystals.

As shown in FIG. 10, a sacrificial layer 202 is formed in the form of a single-crystal on the substrate 200 using ZnO such that the sacrificial layer 202 is oriented in the C-axis direction. The substrate may be a sapphire, SiC or Si substrate. The sacrificial layer 202 composed of ZnO is formed by deposition (e.g. sputtering) on the substrate 200.

Then, as shown in FIG. 11, a buffer layer 250 is formed on the sacrificial layer 202 using dimethylhydrazine (DMHy; N₂H₂(CH₃)₂) as a nitrogen (N) source. The buffer layer 250 is doped with conductive impurities in order to form a light-emitting diode having a perpendicular structure.

The buffer layer 250 is composed of nitride e.g. AlxGayIn1-x-yN in which aluminum (Al) composition X and gallium (Ga) composition Y are in the range of 0<X<1 and 0<Y<1.

Aluminum (Al), gallium (Ga) and indium (In) sources used to form the nitride buffer layer 250 are trimethylaluminum (TMAl), trimethylgallium (TMGa) and trimethylindium (TMIn), respectively.

Then, as shown in FIG. 12, a Group III-V compound semiconductor of AlₓIn_{y}Ga_{1-x-y}N is developed in the form of single crystals on the buffer layer 250 to form a first clad layer 220.

At this time, in the quaternary compound film of AlₓIn_{y}Ga_{1-x-y}N, constituting the first clad layer 220, an aluminum (Al) composition X and an indium (In) composition Y are controlled in an appropriate ratio such that the first clad layer 220 has an energy band gap (i.e. about 4.0 eV).

Specifically, the aluminum (Al) composition X and the indium (In) composition Y, allowing the first clad layer 220 to have an energy band gap of about 4.0 eV, are in the range of 0<X<0.4 and 0<Y<0.4, respectively.

Then, as shown in FIG. 13, a Group III-V compound semiconductor of GaN is developed in the form of single crystals on the first clad layer 220 to form an activation layer 230.

Then, as shown in FIG. 14, a Group III-V compound semiconductor of AlₓIn_{y}Ga_{1-x-y}N is developed in the form of single crystals on the activation layer 230 to form a second clad layer 240.

At this time, an aluminum (Al) composition X and an indium (In) composition Y in the quaternary compound film of AlₓIn_{y}Ga_{1-x-y}N, constituting the second clad layer 240, are determined such that the second clad layer 240 has an energy band gap (i.e. about 4.0 eV).

Specifically, the aluminum (Al) composition X and the indium (In) composition Y, allowing the second clad layer 240 to have an energy band gap of about 4.0 eV, are in the range of 0<X<0.4 and 0<Y<0.4, respectively.

The aluminum (Al) and indium (In) compositions of the first clad layer 220 and the second clad layer 240 may be symmetrical to each other within the respective predetermined ranges.

More specifically, in a case where the aluminum (Al) composition X of the first clad layer 220 and the second clad layer 240 is in the range of 0<X<0.4, when aluminum (Al) of the first clad layer 220 has a first composition, aluminum (Al) of the second clad layer 240 has a second composition different from the first composition. For example, when the first composition A is 0.1, the second composition is 0.3.

By symmetrically controlling the aluminum (Al) composition of the first clad layer 220 and the second clad layer 240 within the desired ranges, it is possible to offset the stress applied to the activation layer 230 and prevent spontaneous polarization.

Similarly, by symmetrically controlling the indium (In) composition Y of the first clad layer 220 and the second clad layer 240 within the desired ranges, it is possible to offset the stress applied to the activation layer 230 and prevent spontaneous polarization.

Then, as shown in FIG. 15, the sacrificial layer 202 interposed between the substrate 200 and buffer layer 250 is chemically removed to separate the substrate 200 from quaternary compound semiconductors 250 and 210.

The separation of the substrate 200 from the remaining structure may be carried out after forming the first clad layer 220 on the buffer layer 250.

In this case, after the buffer layer 250 and the first clad layer 220 are sequentially formed, the activation layer 230 and the second clad layer 240 are formed sequentially on the first clad layer 220.

Then, as shown in FIG. 16, a first electrode 260 is formed under the buffer layer 250 using a conductive material and a second electrode 270 is formed over the second clad layer 240 using a conductive material.

According to the aforementioned fabrication method, a quaternary nitride compound semiconductor light-emitting diode 100 is finally obtained.

As illustrated in the embodiment, the first clad layer 220, the second clad layer 240 and activation layer 230 are Group III-V compound semiconductors employing elements such as aluminum (Al), gallium (Ga), indium (In), phosphorus (P), arsenic (As), nitrogen (N). Alternatively, these layers may employ semiconductors composed of Group II-VI compounds such as ZnO or CdMgZnO.

When the activation layer 230 is a Group III-V nitride compound (AlInGaN) semiconductor, indium (In) and nitrogen (N) compositions are adjusted to InₓGa₁₋ₓN, where 0<X<1.

In addition, in the case of Group II-VI compound (e.g. ZnO and CdMgZnO) semiconductors, the activation layer is composed of ZnO and the clad layer is composed of CdₓMg_{y}Zn_{1-x-y}O, in which the cadmium (Cd) composition X and the magnesium (Mg) composition Y are controlled within the range of 0<X<0.4 and 0<Y<0.33, respectively.

As such, by adjusting cadmium (Cd) and magnesium (Mg) compositions of the first and second clad layers within the desired ranges, it is possible to offset stresses applied to the activation layer and prevent spontaneous polarization.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

### INDUSTRIAL APPLICABILITY

As apparent from foregoing, the light-emitting diode according to an embodiment of the present invention, in the quaternary compound film of AlₓIn_{y}Ga_{1-x-y}N constituting clad layers, an aluminum (Al) composition X and an indium (In) composition Y are determined in an appropriate ratio, thereby adjusting an energy band gap of the clad layers to about 4.0 eV.

Furthermore, under the condition that the clad layers maintains an energy band gap of about 4.0 eV, by allowing the aluminum (Al) and indium (In) compositions of the first clad layer symmetrical to those of the second clad layer, it is possible to offset the stresses applied to an activation layer and prevent spontaneous polarization. As a result, the light-emitting diode can exhibit improved light efficiency.

What is claimed is:

1-21. (canceled)

22. A light-emitting device, comprising:
a light-emitting layer having a first quaternary clad layer with a first material having a first composition ratio and a second material having a second composition ratio, a second quaternary clad layer with a third material having a third composition ratio and a fourth material having a fourth composition ratio, and an activation layer contacted with first clad layer and the second clad layer between them;
a first electrode electrically contacted with the light-emitting layer; and,
a second electrode electrically contacted with the light-emitting layer,
wherein the first quaternary clad layer and the second quaternary clad layer have a predetermined energy band gap by controlling the first, second, third and fourth composition ratio, for removing the piezoelectric field and spontaneous polarization applied to the activation layer.

23. The light-emitting device according to claim 22, wherein the first quaternary clad layer and the second quaternary clad layer are composed of AlₓIn_{y}Ga_{1-x-y}N.

24. The light-emitting device according to claim 23, wherein the first material and the third material are aluminum (Al), and the second material and the fourth material are indium (In).

25. The light-emitting device according to claim 24, wherein the first composition ratio (X) and the third composition ratio (X′) are adjusted in the range of 0<X or X′<0.4.

26. The light-emitting device according to claim 24, wherein the second composition ratio (Y) and the fourth composition ratio (Y′) are adjusted in the range of 0<Y or Y′<0.4.

27. The light-emitting device according to claim 24, wherein the first and second clad layers have an energy band gap of about 4.0 eV.

28. The light-emitting device according to claim 24, wherein the first and second clad layers have an energy band gap of about 4.0 eV.

29. The light-emitting device according to claim 22, wherein the first quaternary clad layer and the second quaternary clad layer are composed of CdₓMg_{y}Zn_{1-x-y}O.

30. The light-emitting device according to claim 29, wherein the first material and the third material are cadmium (Cd), and the second material and the fourth material are magnesium (Mg).

31. The light-emitting device according to claim 29, wherein the first composition ratio (X) and the third composition ratio (X′) are adjusted in the range of 0<X or X′<0.4.

32. The light-emitting device according to claim 29, wherein the second composition ratio (Y) and the fourth composition ratio (Y′) are adjusted in the range of 0<Y or Y′<0.33.
